(19) United States
(12) Patent Application Publication
(10) Pub. No.: US 2008/0055443 A1
(43) Pub. Date: Mar. 6, 2008

(54) Image pickup device including a solar cell and apparatus therefor

(75) Inventors: Satoru Okamoto, Asaka-shi (JP); Masayuki Hayashi, Ashigarakami-gun (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: FUJIFILM CORPORATION, Tokyo (JP)

(21) Appl. No.: 11/896,401

(22) Filed: Aug. 31, 2007

(30) Foreign Application Priority Data
Sep. 5, 2006 (JP) 2006-240570

(51) Int. Cl. H04N 3/14

(52) U.S. Cl. 348/298; 348/E03.016

(57) ABSTRACT

An image pickup device has a transparent insulation film formed on the primary surface of a semiconductor substrate and a solar cell formed on the insulation film. The solar cell has a transparent electrode film, a p-type conductive film, an n-type conductive film and a transparent electrode film stacked in this order from the bottom. Three photoelectric conversion films are stacked on the solar cell for sensing red, green and blue components, respectively. The solar cell is sensitive to infrared wavelengths. The image pickup device thus allows a battery cell to be reduced in volume.

### BACKGROUND OF THE INVENTION

1. Field of the Invention

The present invention relates to a solid-state image pickup device and an image pickup apparatus including an image pickup device.

2. Description of the Background Art

Conventionally, a solid-state image pickup device has been developed which has photodiodes integrated. Such a solid-state image pickup device having photodiodes includes a number of photosensitive elements disposed at different positions in a common plane with different colors sensed at horizontally different positions. In contrast, recently, Japanese patent laid-open publication No. 2003-332551 has proposed an image pickup device comprising a stack of three layered photoelectric conversion films of organic material. Those films are sensitive to a specific light component of different color. Such an image pickup device having organic films has an advantage that the same horizontal position of the three layered films can detect the three primary colors of light, red (R), green (G) and blue (B).

Digital cameras incorporating an image pickup device including photodiodes or comprising a stack of three layered photoelectric conversion films of organic material receive a strong need for compactness. However, when such a digital camera offers higher performance features, the camera consumes more power and thus a battery cell embedded therein is large in size and heavy in weight, thereby being prevented from compactness.

### SUMMARY OF THE INVENTION

It is an object of the invention to provide an image pickup device and an image pickup apparatus applicable to both an image pickup device including photodiodes and an image pickup device comprising a stack of layered photoelectric conversion films with its battery cell reduced in volume.

In accordance with the invention, an image pickup device comprises: a photoelectric converter for converting incident light to a corresponding electric signal charge; a charge storage for storing the signal charge obtained by the photoelectric converter; and a solar cell, wherein the photoelectric converter and the solar cell are stacked in a direction in which the incident light impinges the image pickup device. Therefore, the image pickup device operates so that electric power is generated by the solar cell and supplied to an image pickup apparatus or a camera including the device, thereby reducing the volume of a battery cell installed in the camera or an external battery cell, and being capable of photographing an increased number of frames of image as well.

It is preferable that in the image pickup device, the solar cell at least be sensitive to infrared wavelengths. In this case, the image pickup device, sensitive to a visible region, may effectively utilize electric power caused by infrared rays unnecessary for image-shooting of the image pickup device. Further, when the solar cell is disposed in proximal with respect to the photoelectric converter in a direction in which the incident light impinges on the device, it is possible to eliminate unnecessary infrared rays which give adverse effect on photographing. Conventionally, infrared rays are filtered by an infrared low-pass filter. According to the invention, however, it is advantageous in that an infrared low-pass filter is not necessary.

The image pickup device may have the solar cell disposed in distal with respect to the photoelectric converter in the direction of the light impinging. In this case, the solar cell may be sensitive to radiation other than infrared radiation since in that structure visible light is absorbed by the photoelectric converter and only infrared light enters the solar cell.

According also to the invention, the solar cell may preferably be disposed at the same vertical level, or in one and the same layer, as the charge storage. In this case, interconnection is simplified and manufacturing cost is reduced. The reason therefor is that the solar cell can be fabricated by simultaneously patterning with the charge storage, etc. Alternatively, the charge storage may be disposed in distal with respect to the solar cell in the direction of the incident light impinging. In the latter case, the area of the solar cell increases, thereby advantageously resulting in increasing the amount of electric power generated by the battery.

The solar cell may be disposed in proximal with respect to the photoelectric converter in the direction of the incident light impinging. In this case, the solar cell is preferably optically transmissive. When a solar cell not transmissive is used, it is preferable that the solar cell be made thinner or be disposed partially on the surface of the image pickup device, rather than over the entire surface of the device.

The solar cell may be disposed at an intermediate level of the photoelectric converter, rather than being disposed in distal or proximal with respect to the photoelectric converter in the direction of the incident light impinging.

In the image pickup device described above, the charge storage may be of a CMOS (Complementary Metal-Oxide Semiconductor) structure or formed of an organic semiconductor material.

An image pickup apparatus including the above-described image pickup device may preferably comprise a voltage detector for detecting the output voltage of the solar cell; and a controller operative in response to the voltage detector for controlling the output of the solar cell. In this case, the output of the solar cell can be appropriately controlled in response to the output voltage of the solar cell.

According to the invention, the image pickup device operates so that electric power is generated by the solar cell and supplied to an image pickup apparatus including the device, thereby reducing the volume of a battery cell installed in the device, e.g. a camera, or an external battery cell, and increasing the number of frames of image to be photographed.

### BRIEF DESCRIPTION OF THE DRAWINGS

The objects and features of the present invention will become more apparent from consideration of the following detailed description taken in conjunction with the accompanying drawings in which:

FIG. 1 is a schematic plan view showing the layout on the primary surface of a solid-state image pickup device having a stack of photoelectric conversion layers according to an embodiment of the invention;

FIG. 2 shows an enlarged schematic view of an area enclosed by a frame II shown in FIG. 1;

FIG. 3 is a schematic cross-sectional view taken along a line III-III in FIG. 2;

FIG. 4 is a schematic view of the surface of the semiconductor substrate with the components such as photoelectric conversion films, etc., on the semiconductor substrate removed from the situation shown in FIG. 2;

FIG. 5 is a schematic cross-sectional view taken along a line V-V in FIG. 4;

FIG. 6 is a schematic cross-sectional view of a solid-state image pickup device having a stack of photoelectric conversion layers according to an alternative embodiment of the invention;

FIG. 7 is a schematic block diagram showing the general configuration of an embodiment of a digital camera including the solid-state image pickup device according to the invention; and

FIG. 8 is a flow chart useful for understanding power supply control of the camera with an image pickup device having organic films and serving as a solar cell according to the invention.

### DESCRIPTION OF THE PREFERRED EMBODIMENTS

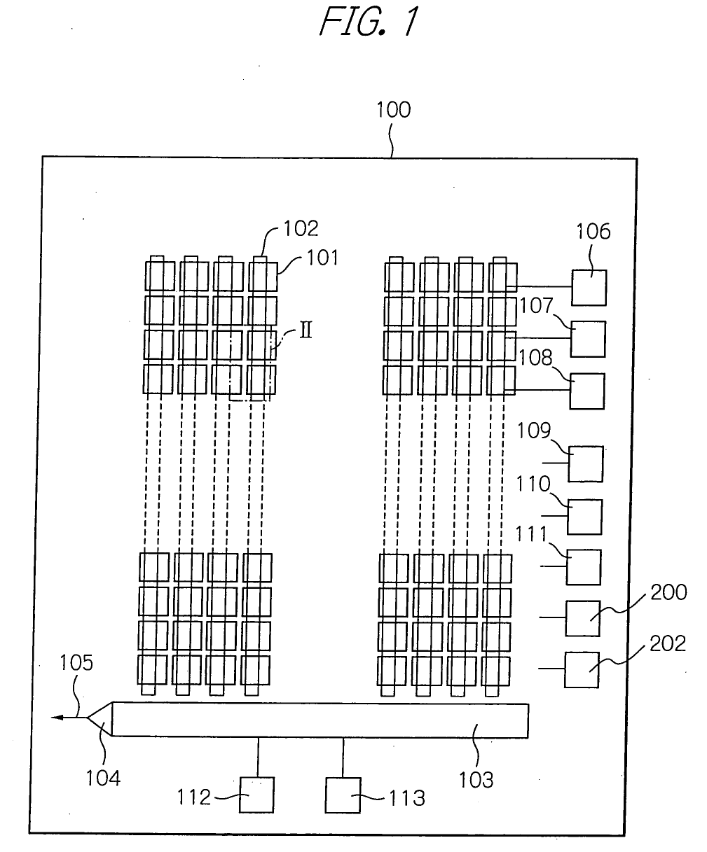

Embodiments of an image pickup device according to the invention will be described below in detail with reference to the accompanying drawings. FIG. 1 shows in a schematic view the primary surface of a solid-state image pickup device 100 having a stack of photoelectric conversion layers. The image pickup device 100 includes as a photoelectric converter three layered photoelectric conversion films of an organic material. In this embodiment, a solar cell is disposed below the photoelectric conversion films, i.e. in distal with respect to the photoelectric conversion films in the direction in which the incident light impinges on the imaging surface of the photosensitive device 44. The present invention is not limited to a solid-state image pickup device having a stack of photoelectric conversion layers, but may be applied to a solid-state image pickup device including photodiodes.

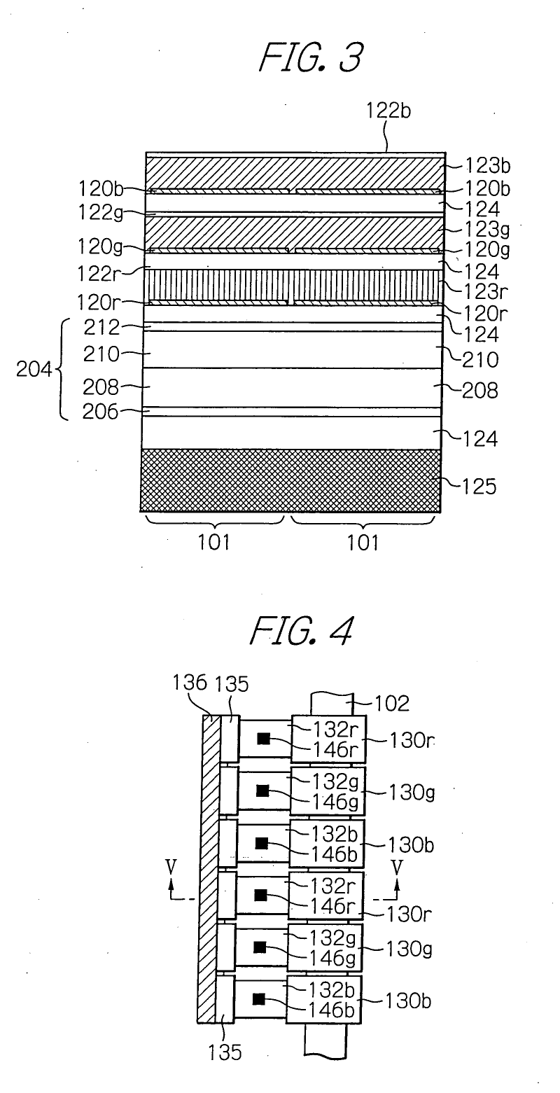

The solid-state image pickup device 100 having the stack of photoelectric conversion layers includes an array of photosensitive cells 101 formed, in this embodiment, in a square lattice pattern. On one of the primary surface of a semiconductor substrate 125, FIG. 3, which is positioned below the photosensitive cells 101, vertical transfer paths, e.g. column CCD (Charge-Coupled Device) registers, 102 are formed so that each of the column registers 102 is arranged overlapping a corresponding column of photosensitive cells 101. Further, a horizontal transfer path, e.g. a row, or line, CCD register, 103 is formed in the lower portion of the semiconductor substrate.

To the output end of the horizontal transfer path 103, connected is an amplifier 104. Signal charges stored in the photosensitive cells 101 are first transferred over associated one of the vertical transfer paths 102 to the horizontal transfer path 103 row by row, i.e. line by line, and then transferred over the horizontal transfer path 103 to the amplifier 104, which in turn outputs the charges in the form of output signal 105.

On the primary surface of the semiconductor substrate, contact pads 106, 107 and 108 are formed, which are connected to later-described transfer electrodes, which are formed on associated one of the vertical transfer paths 102 at least partially overlapping the latter. Further, on the surface of the semiconductor substrate, contact pads 109, 110 and 111 are formed which are connected to common electrode films described, later, of the photosensitive cells 101, and also contact pads 112 and 113 are formed for transferring signal charges over the horizontal transfer path 103. Additionally, on the surface, contact pads 200 and 202 are formed which are connected to transparent electrodes, also described later, functioning as a solar cell.

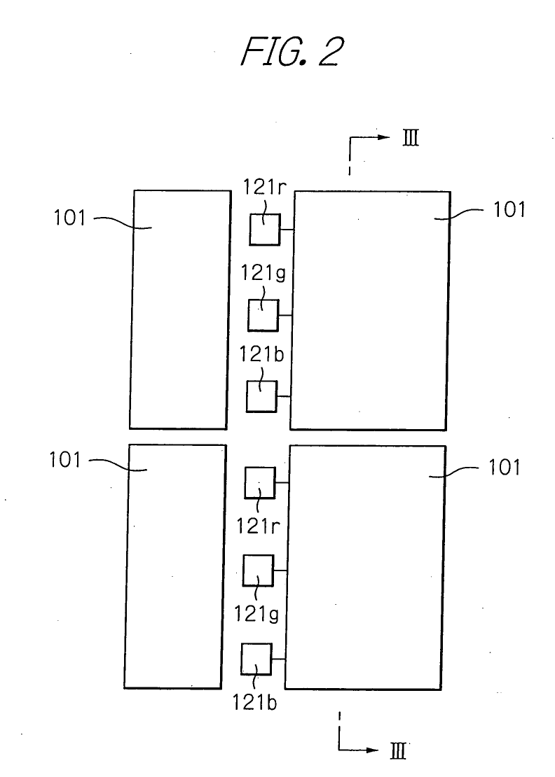

Now, FIG. 2 is an enlarged schematic view of then area enclosed by a rectangular frame II in FIG. 1 which surrounds four of the photosensitive cells 101. Between one column and an adjacent column of the photosensitive cells 101, in this embodiment, three connector pads 121r, 121g and 121b are disposed per photosensitive cell. In the following also, subscripts r, g and b represent color components of incident light to be sensed, i.e. red (R), green (G) and blue (B), respectively.

FIG. 3 is a schematic sectional view taken along a line III-III in FIG. 2. On the primary surface of the semiconductor substrate 125, first a transparent insulation film 124 is formed, on which a solar cell having a transparent electrode film 206, a p-type conductive film 208, an n-type conductive film 210 and a transparent electrode film 212 are stacked, or deposited, in this order from the bottom in the figure. The stack of transparent electrode film 206, p-type conductive film 208, n-type conductive film 210 and transparent electrode film 212 may not be partitioned, or separately provided, on a photosensitive cell by cell 101 basis, but may be formed unitarily, i.e. as a single stack, over the entire array of photosensitive cells 101, or photosensitive surface. The stack of films may be separately provided for each of the individual photosensitive cells 101.

On the solar cell 204, another transparent insulation film 124 is stacked, on which stacked are electrode films 120r partitioned in accordance with the photosensitive cells 101 to serve as “pixel electrode films”. On the pixel electrode films 120r, a photoelectric conversion film 123r is stacked which is adapted for producing a red (R) light component signal. The photoelectric conversion film 123r need not be partitioned in accordance with the photosensitive cells 101, but may be formed as a single sheet over the entire array of photosensitive cells 101.

On the photoelectric conversion film 123r, a common electrode film 122r is stacked also as a single sheet which is common to ones of the photosensitive cells 101 which are adapted for producing a red component signal. On the common electrode film 123r, another transparent insulation film 124 is stacked.

On the last-stated insulation film 124, other pixel electrode films 120g are stacked which are partitioned in accordance with the photosensitive cells 101. On the other pixel electrode films 120g, another photoelectric conversion film 123g is stacked for producing a green (G) light component signal as a single sheet in the same manner as described above. On the photoelectric conversion film 123g, another common electrode film 122g is stacked, on which another transparent insulation film 124 is stacked.

On the insulation film 124 mentioned just above, other pixel electrode films 120b are stacked which are also partitioned in accordance with the photosensitive cells 101. On the pixel electrode films 120b, another photoelectric conversion film 123b is stacked adapted for producing a blue (B) light component signal as a single sheet in the same manner as described above. On the photoelectric conversion film 123b, another common electrode film 122b is stacked.

In terms of each photosensitive cell 101, the pixel electrode films 120b, 120g and 120r of are aligned in the order in the direction of incident light. More specifically, in the solid-state image pickup device 100 having the stack of photoelectric conversion layers according to the instant embodiment, each of the photosensitive cells 101 is sensitive to the three colors, red (R), green (G) and blue (B). The word “pixel” simply referred to as hereinafter means one of the photosensitive cells 101 which is sensitive to the three colors whereas the term “color pixel”, “red pixel”, “green pixel” or “blue pixel” means a partial pixel, i.e. a section of the photoelectric conversion film sandwiched between the common electrode film and the pixel electrode films for producing a corresponding color component signal.

The connector pads 121b 121g and 121r shown in FIG. 2 are connected to a blue pixel electrode film 120b, a green pixel electrode film 120g and a red pixel electrode film 120r, respectively. Further, the contact pads 200 and 202 shown in FIG. 1 are connected to the electrode films 206 and 212, respectively, and the contact pads 109, 110 and 111 are connected to the common electrode films 122b, 122g and 122r, respectively.

The transparent electrode films 206, 212, 122r, 122g, 122b, 120r, 120g, and 120b may be homogeneous and include, but not limited to, tin oxide (SnO₂), titanium oxide (TiO₂), indium oxide (InO₂) or indium titanium oxide (ITO), for example.

The p-type conductive film 208 and n-type conductive film 210 of the solar cell 204 may be made of any one of transparent material, opaque material, and organic material. When the p-type conductive film 208 made of a transparent material is selected, a p-type transparent conductive oxide film may be used as the film 208. The p-type transparent conductive oxide film may be implemented by copper oxide with delafossite structure. In particular, the p-type transparent conductive oxide film is made of a material such as CuAlO₂, CuInO₂, CuGaO₂, or SrCu₂O₂. When the n-type conductive film 208 made of a transparent material is selected, an n-type transparent conductive oxide film may be used as the film 208. In particular, the n-type transparent conductive oxide film is made of a material such as ZnO, In₂O₃, SnO₂, CdIn₂O₄, MgIn₂O₄, ZnGa₂O₄, InGaZnO₄, etc.

Examples of an opaque material include crystalline silicon, polycrystalline silicon, amorphous silicon, etc. Examples of a p-type material include non-metal phthalocyanine, various metal phthalocyanine, triphenylamine derivatives, hydrazone based derivatives, stilbene based derivatives, etc. Further, the p-type organic semiconductor layer may be formed, for example, by vacuum evaporation or solvent coating. Examples of an n-type material include C60, C70-fullerene. Fullerene films may be formed by vacuum evaporation or by forming fullerene derivatives of higher solubility and using solvent coating method.

The photoelectric conversion films 123r, 123g and 123b may be a single-or a multiple-layer film. Examples of materials of the photoelectric conversion films include inorganic materials such as silicon or compound semiconductor, organic materials containing organic semiconductor, organic pigment, etc., and quantum dot-deposited films made from nano-particles.

FIG. 4 schematically shows the surface of the semiconductor substrate 125 with the components disposed above the insulation film 124, FIG. 3, (light-blocking, or optically shielding, film 144 described later) removed from the situation shown in FIG. 2. Three transfer electrodes 130r, 130g and 130b per pixel 101 are arranged. Adjacent the transfer electrode 130r, a charge storage region 132r is formed for storing signal charges generated in a red pixel of the pixel 101. Further, adjacent the transfer electrode 130g, a charge storage region 132g is formed for storing signal charges generated in a green pixel of the pixel 101, and adjacent the transfer electrode 130b, a charge storage region 132b is formed for storing signal charges generated in a blue pixel of that pixel 101.

Below the transfer electrodes 130r, 130g and 130b, a transfer channel 102 is formed, between which and the charge storage regions 132r, 132g and 132b, potential barriers are produced, and the transfer electrodes 130r, 130g and 130b extend across the region in which the potential barriers are formed over the ends of the charge storage regions 132r, 132g and 132b. In particular, the transfer electrodes 130r, 130g and 130b serve also as a readout electrode for reading out signal charges of respective colors, i.e. red, green, and blue color components.

In the central portions of the charge storage regions 132r, 132g and 132b, columnar interconnecting electrodes 146r, 146g and 146b are formed to interconnect the charge storage regions 132r, 132g and 132b to the red pixel electrode film 120r, green pixel electrode film 120g and blue pixel electrode film 120b, respectively.

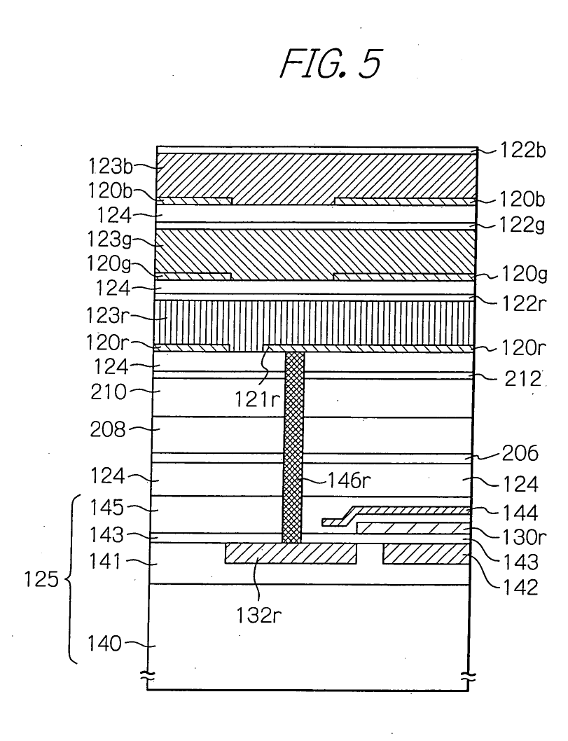

FIG. 5 is a schematic sectional view of the cross section, taken along a line V-V in FIG. 4 and including also the components stacked on the semiconductor substrate 125 shown in FIG. 3. On the surface portion of an n-type semiconductor substrate 140, a p-well layer 141 is formed, in which formed are an n-type semiconductor region 142 making up a charge transfer channel and the charge storage region 132r having the above-described connection electrode 146r formed on its central portion for storing signal charges of red color component.

Over the p-well layer 141, a gate insulation film 143 is formed, on which the transfer electrode, or read out electrode, 130r is formed. Further, the columnar interconnecting electrode 146r is formed through the gate insulation film 143 to the connector pad 121r of the red pixel electrode film 120r shown in FIG. 2.

Over the electrode 135 and transfer electrode 130r, an insulation film 145 is formed, in which a light-blocking film 144 is embedded, and over which the lowermost, in FIG. 3, insulation film 124 shown is formed. The semiconductor substrate 125 shown in FIG. 3 corresponds in FIG. 5 to the components from the n-type semiconductor substrate 140 up to the insulation film 145.

FIG. 5 is a cross-sectional view taken along the line V-V in FIG. 4, and therefore in FIG. 5 the interconnecting electrode 146r connected to the red-pixel electrode film 120r is shown standing upright. However, interconnecting electrodes connected to the green-pixel electrode 120g and the blue-pixel electrode 120b, respectively, are positioned standing upright on the backside of and in front of the paper, and therefore not depicted in the figure. Further, the arrangement and structure of the charge storage region 132r, transfer electrode 130r, and charge transfer channel 142 around the interconnecting electrode 146r for red color (R) component can likewise apply to those for the remaining color components.

According to the invention, the solar cell 204 is implemented as a photoelectric conversion layer made of a photoconductive material sensitive to infrared radiation to thereby effectively absorb infrared energy of the solar beam, thereby providing a high photoelectric conversion efficiency. It is preferable to use an optically transparent, electro-conductive layer which is high in electrical conductivity and optical transparency from visible to infrared rays in combination with a photoconductive material sensitive to infrared radiation. Examples of the conductive transparent layer include a transparent conductive layer doped with indium oxide, which is formed by applying a solution containing organic indium compound to a substrate and thermally decomposing the substances of the solution. Examples of the transparent layer having a relatively low conductivity include a layer of zinc oxide which is high in transmissivity to light having wavelengths ranging from visible light to infrared.

Examples of a photoconductive material contained in the photoelectric conversion layer sensitive to infrared radiation include silicon (amorphous, monocrystalline, polycrystalline), GaAs, inorganic compound such as CdS, squarylium compound, organic compound such as phthalocyanine compound. The photoconductive material may be any material capable of absorbing infrared radiation of wavelengths not less than 780 nm. The photoconductive material may be doped with additives such as boron, phosphorous, etc., in order to provide p-type or n-type material.

In this illustrative embodiment, the charge storage section is disposed under the solar cell. The solar cell may however be formed in the same layer as the charge storage section. Further in the embodiment, the charge storage section has a CMOS (Complementary Metal-Oxide Semiconductor) circuit structure. It may however comprise an organic semiconductor.

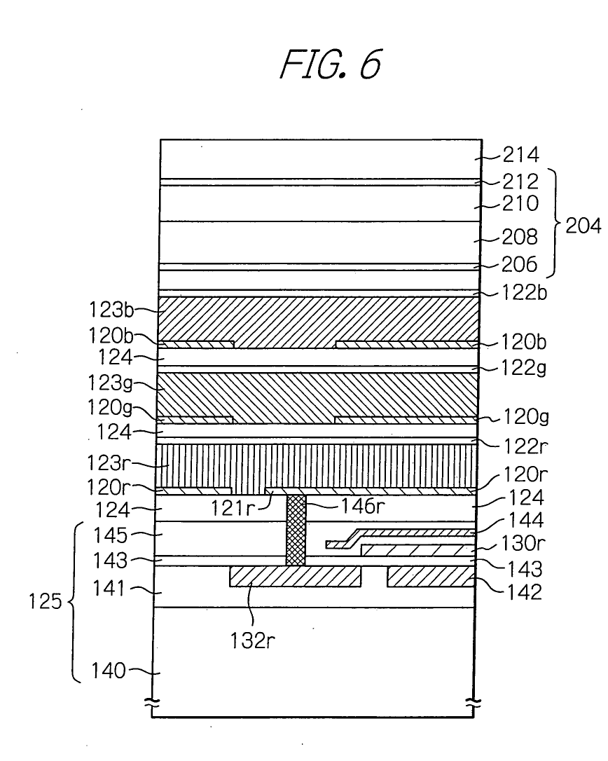

An alternative embodiment of the invention will now be described. In the alternative embodiment, the solar cell 204 is disposed above the photoelectric converter, i.e. in proximal with respect to the photoelectric converter in the direction of the incident light impinging. FIG. 6 schematically shows the cross-sectional of the alternative embodiment of the solid-state image pickup device having the stack of photoelectric conversion layers. FIG. 6 corresponds to FIG. 5 showing the previous embodiment. The alternative embodiment is the same as the previous embodiment except that the solar cell 204 is positioned above the photoelectric converter. The configuration of the solar cell 204 per se may be the same as in the previous embodiment. Like elements and components are designated with the same reference numerals and a repetitive description thereof will be omitted.

In the previous embodiment, the solar cell 204 may be optically opaque. However, in the alternative embodiment, it is preferable that the solar cell 204 be light-transmissive, or optically transparent. When an opaque solar cell is used, the solar cell is preferably formed thinner. In particular, the solar cell 204 is preferably sensitive to infrared wavelengths and insensitive to the red band of the visible light. The reason therefor is that if the solar cell 204 were sensitive to the red band, it would absorb the red light component so as not to output the sufficient level of a signal of red component from the photosensitive cell. Over the solar cell 204, a transparent protective film 214 is formed.

The benefits of the alternative embodiment are that since the solar cell 204 is sensitive to infrared wavelengths, a substantial portion of infrared radiation is absorbed by the solar cell 204 before infrared light enters the RGB photoelectric conversion films, and therefore the color purity is improved, especially in respect of the layer sensitive to longer wavelengths, e.g. red.

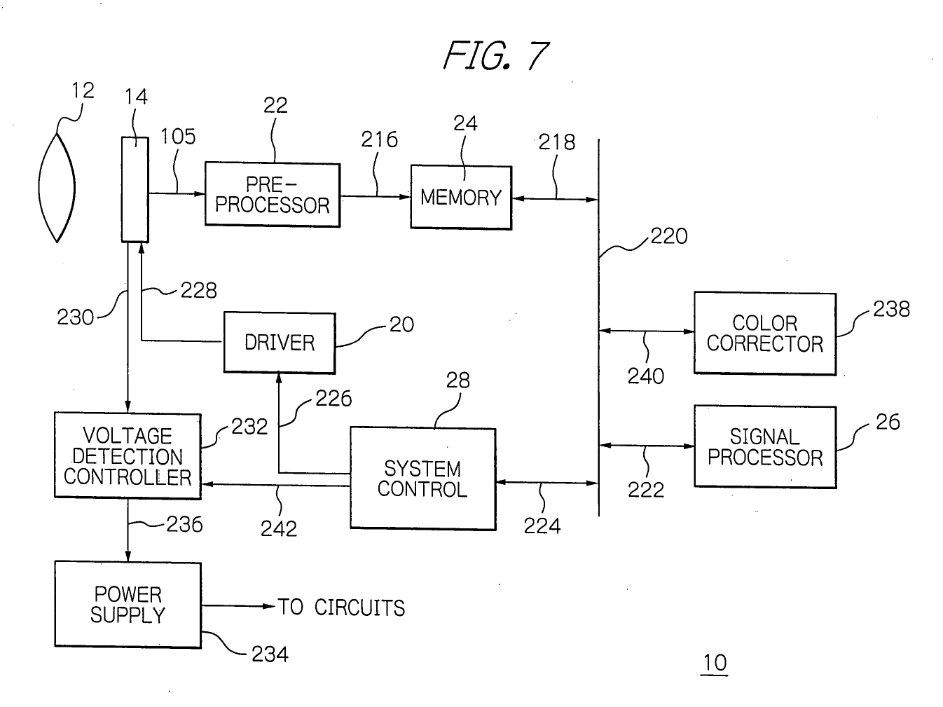

An illustrative embodiment of the image pickup apparatus including such an image pickup device will now be described with reference to FIG. 7. The embodiment is directed to an application where the solid-state image pickup device according to the invention is included in a digital camera 10. Parts or elements not directly pertinent to understanding the invention are omitted from the drawings and description.

The digital camera 10 has an optics 12 focusing light incoming from an object scene onto the image pickup device of an image pickup section 14. The image pickup section 14 includes the solid-state image pickup device 100 shown in FIG. 1. In the solid-state image pickup device 100, light incident thereon is separated into different colors, e.g. primary color components, which is in turn converted to signal charges by the photosensitive cells 101, the charges being stored and output in the form of electrical signal. The solid-state image pickup device 100 operates in such a manner that the signal charges stored in the photosensitive cells are transferred to the vertical transfer paths 102 and sequentially transferred in the vertical direction of the imaging frame, or photosensitive cell array. The signal charges vertically transferred are further transferred over the horizontal transfer path 103 and supplied as an output signal 105 to a pre-processor 22. Signals are designated with reference numerals specifying connections on which they appear.

The camera 10 further includes a pre-processor 22 serving as an analog front end (AFE). The AFE function performs a correlated-double sampling (CDS) on the analog electrical signal 105 supplied thereto in order to reduce noise, and digitizes the analog electrical signal from which noise components have been removed, i.e. performs analog-to-digital (A/D) conversion. The pre-processor 22 supplies a digitized signal 216 to a memory 24.

The memory 24 temporarily stores therein the digitized signal 216 supplied thereto to output the signal 216 thus stored to a signal processor 26 as a digital signal 218 over a bus 220 and a signal line 222.

The signal processor 26 performs signal processing on the digital signal 218 supplied thereto. The signal processor 26 includes automatic focusing (AF) control, automatic exposure (AE) control, automatic white balance (AWB) control, and the like, which are not specifically shown. The AF control adjusts the focusing of the optics 12 in response to produced image data. The AE control calculates an evaluation value of produced image data in order to adjust settings of the aperture value and shutter speed. The AF and AE controls send a control signal, not shown, to a system control 28 over a signal line 222, a bus 220, and a signal line 224. The AWB control adjusts the white balance setting based on produced image data.

The system control 28 generates a control signal for controlling the image pickup section 14 to output the signal to a driver 20 over the signal line 226. The driver 20 generates various timing signals such as vertical and horizontal synchronous signals, a field shift gate signal, vertical and horizontal timing signals, etc., and outputs those signals to the solid-state image pickup device 100 of the image pickup section 14 over the signal line 228.

The image pickup device 100 according to the embodiment differs from conventional image pickup devices, among others, in that the image pickup device 100 of the embodiment includes output terminals 200 and 202 for outputting electric power generated by the solar cell 204. The output terminals 200 and 202 are connected via a power line 230 to a voltage detection controller 232. The voltage detection controller 232 is adapted to detect a voltage level. If the voltage level detected is above a predetermined voltage level, the controller 232 supplies the electric power generated by the solar cell 204 to a power supply 234 over a power line 236. The power supply 234 regulates the voltage of the electric power supplied from the controller 232 to a predetermined level voltage. The power supply 234 is further adapted to supply, together with the electric power supplied from a battery cell, not shown, incorporated in the camera 10, the resultant power to the components of the camera 10. If the voltage level detected is below the predetermined voltage level, the voltage detection controller 232 does not supply the electric power generated by the solar cell 204 to the power supply 234. In this case, the power supply 234 is controlled so that only the battery cell feeds electric power to the components of the camera 10.

The voltage detection controller 232 performs the above-described processing during an image shooting. The voltage detection controller 232 determines whether or not an image shooting is currently carried out from a signal supplied from the system control 28 over a signal line 242. The voltage detection controller 232 may be adapted to execute the above-described processing when the image shooting is not carried out. For that aim, the system may be structured such that a lens cap is removed from the camera lens 12 so as to allow the solar cell 204 to generate electric power, which is in turn applied to the battery cell via the power supply 234 to charge the battery cell.

The power supply 234 may alternatively be designed, in order to separately control, as desired, the power supply systems of the solar cell 204 and the battery cell from each other so as to supply predetermined components of the camera 10 with the electric power of the solar cell 204 dependently upon its amount currently available.

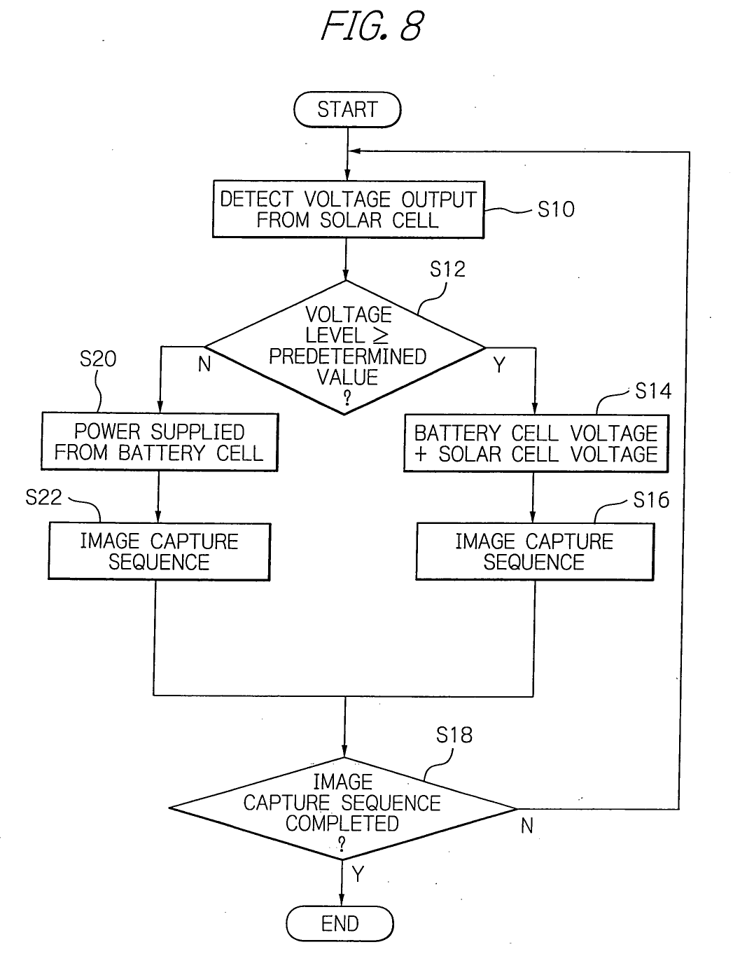

How to control the power supply to the camera will be now described with reference to FIG. 8. FIG. 8 is a flow chart useful for understanding control of power supply to the camera 10 comprising the image pickup device including organic films and the solar cell according to the invention. When the user turns on a power switch, not shown, of the camera 10, and depresses a shutter button, also not shown, to instruct the camera 10 to prepare for photographing, the voltage detection controller 232 detects the level of an output voltage from the solar cell 204 of the image pickup device 100 (step S10). Thereafter, it is determined whether or not the detected level of the output voltage is substantially equal to or above the predetermined value (step S12). If the answer of the step S12 is positive, or “Y”, then the controller 232 allows the solar cell 204 to supply the electric power to the power supply 234. The power supply 234 then incorporates the electric power of the solar cell 204 to that of the battery cell incorporated in the camera 10 to supply the resultant power to the components of the camera 10 (step S14). Thereafter, the camera 10 starts an image capture sequence and then performs various processing for imaging signals (step S16). The voltage detection controller 232 determines whether or not the image capture sequence is completed, based on a signal from the system control 28 (step S18). If the answer of the step S18 is negative, or “N”, then the operation returns to the step S10. If the answer is positive, then the operation ends.

In step S12, if the level of the output voltage is below the predetermined value, then the voltage detection controller 232 does not provide the electric power of the solar cell 204 to the power supply 234. The power supply 234 provides only the electric power supplied from the battery cell to the components of the camera 10 (step S20). Thereafter, the camera 10 starts an image capture sequence and then performs various processing for imaging signals (step S22). Then, the operation of the voltage detection controller 232 proceeds to step S18.

The digital camera 10 may include a color corrector 238 as shown in FIG. 7. The inclusion of the color corrector 238 is advantageous for the following reason. In order to prevent the part of the photosensitive cells which is sensitive to a red component from being affected by an infrared component, that part of the photosensitive cells may sometimes have its range of wavelengths reduced to securely exclude the infrared band. In that case, the level of the output signal from the photosensitive cells may be reduced so that the red coloring of a resultant image could be decreased. In order to prevent such a situation in the illustrative embodiment, the color corrector 238 is provided to compensate for red coloring lost accordingly.

The color corrector 238 receives from the memory 24 red data in an image signal over a signal line 240. The color corrector 238 multiplies the received data by a predetermined constant greater than unity. The resultant data is supplied over the signal line 240 again to the memory 24 and stored therein. A value for the predetermined constant is measured before shipping the camera 10 and stored in a non-volatile memory, not shown, of the camera 10 upon shipping. Alternatively or in addition, a value for that constant may be changed by the user after shipped.

The entire disclosure of Japanese patent application No. 2006-240570 filed on Sep. 5, 2006, including the specification, claims, accompanying drawings and abstract of the disclosure, is incorporated herein by reference in its entirety.

While the present invention has been described with reference to the particular illustrative embodiments, it is not to be restricted by the embodiments. It is to be appreciated that those skilled in the art can change or modify the embodiments without departing from the scope and spirit of the present invention.

What is claimed is:

1. An image pickup device comprising:
a photoelectric converter for converting incident light to a corresponding electric signal charge;
a charge storage for storing the signal charge obtained by said photoelectric converter; and
a solar cell,
said photoelectric converter and said solar cell being stacked in a direction in which the incident light impinges on said device.

2. The image pickup device in accordance with claim 1, wherein said solar cell is sensitive to an infrared wavelength.

3. The image pickup device in accordance with claim 1, wherein said solar cell is disposed in distal with respect to said photoelectric converter in the direction.

4. The image pickup device in accordance with claim 3, wherein said solar cell is disposed in a layer common to said charge storage.

5. The image pickup device in accordance with claim 3, wherein said charge storage is disposed in distal with respect to said solar cell in the direction.

6. The image pickup device in accordance with claim 1, wherein said solar cell is disposed in proximal with respect to said photoelectric converter in the direction.

7. The image pickup device in accordance with claim 5, wherein said solar cell is optically transmissive.

8. The image pickup device in accordance with claim 1, wherein said charge storage has a CMOS (Complementary Metal-Oxide Semiconductor) structure.

9. The image pickup device in accordance with claim 1, wherein said charge storage is formed of an organic semiconductor material.

10. An image pickup apparatus comprising:
a photoelectric converter for converting incident light to a corresponding electric signal charge;
a charge storage for storing signal the signal charge obtained by said photoelectric converter;
a solar cell;
a voltage detector for detecting a voltage of an output of said solar cell; and
a controller operative in response to said voltage detector for controlling the output of said solar cell,
said photoelectric converter and said solar cell being stacked in a direction the incident light impinges on said device.

11. A method for controlling an image pickup device, comprising the steps of:
preparing an image pickup device including a photoelectric converter for converting incident light to a corresponding electric charge and a solar cell stacked on the photoelectric converter in a direction of the incident light impinging on the device;
detecting a voltage of an output of the solar cell; and
controlling the output of the solar cell based on a result of said step of detecting.
